(19) United States
(12) Patent Application Publication
(10) Pub. No.: US 2004/0011279 A1
(43) Pub. Date: Jan. 22, 2004

(54) Method of manufacturing semiconductor device

(75) Inventor: Kwang Chul Joo, Yongin-Shi (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 10/325,842

(22) Filed: Dec. 23, 2002

(30) Foreign Application Priority Data
Jul. 18, 2002 (KR) 2002-42166

(51) Int. Cl. C30B 23/00; C30B 25/00; C30B 28/12; C30B 28/14; H01L 21/8242; H01L 21/302; H01L 21/461

(52) U.S. Cl. 117/88; 438/689

(57) ABSTRACT

The present invention relates to a method of manufacturing a semiconductor device. The method includes forming a first doped polysilicon layer being a lower electrode on a semiconductor substrate, forming a Ta₂O₅ dielectric film using a carbon-free precursor and reaction gases, and forming an upper electrode on the dielectric film. As such, the Ta₂O₅ dielectric film is formed using a carbon-free precursor. The level of the leakage current is reduce, the insulating breakdown voltage is increased and reliability of the device is improved, particularly if the Ta₂O₅ dielectric thin film is used as an inter-poly dielectric material.

### BACKGROUND OF THE INVENTION

1. Field of the Invention

The invention relates generally to a method of manufacturing a dielectric film in a semiconductor device, and more particularly to, a technology of manufacturing a Ta₂O₅ dielectric film using a TaF₅ precursor from which carbon component is removed.

2. Description of the Prior Art

In ONO (oxide/nitride/oxide) inter-poly dielectric thin film, which has been used for a cell transistor of a flash memory device being a nonvolatile memory device, it is difficult to reduce the thickness of an oxide film that is grown on a doped polysilicon layer by a thermal oxidization method due to degradation effect caused by high-concentration phosphorus of the floating gate, a high coupling density and irregularity in the thickness caused by oxidization of the doped polysilicon layer. Thus, there is a limit in securing sufficient capacitance for next generation of flash memory products.

As an alternative to this, there is an increasing interest on a thin Ta₂O₅ film. As the conventional thin Ta₂O₅ film has an unstable stoichiometry, however, Ta atoms of substitutional type (vacancy atoms) due to compositional difference between Ta and O exist within the thin film. In other words, as Ta₂O₅ has an unstable chemical composition itself, the substitution type Ta atoms of an oxygen vacancy state always exist locally within the thin film. Therefore, in order to stabilize the unstable stoichiometry of Ta₂O₅ itself to prevent the leakage current, additional oxidization processes for oxidizing the substitution type Ta atoms within the thin film are required.

Furthermore, Ta atoms and water (H₂O) exist together with impurities such as carbon atoms, carbon compounds (C, CH₄ and C₂H₄, etc.) due to reaction of an organic material of Ta (OC₂H₅)₅, a precursor of Ta₂O₅, and 2 (or N₂O) gas when the thin film is formed. As a result, the leakage current is increased through the inter-poly dielectric film from the floating gate in the cell transistor due to carbon atoms, ions and radicals within the thin Ta₂O₅ film as an impurity. Thus, there is a possibility that the dielectric characteristic will be easily degraded.

In the conventional method of the thin Ta₂O₅ film, a LP-MOCVD (low-pressure metal organic chemical vapor deposition) method has been used. Also, metal organic compounds having a relatively low boiling point such as Ta (OC₂H₅)₅ [tantalum pentaethoxide], TaCl₂(OC₂H₅)₂C₅H₇O₂(dichloro-diethoxy-acetylacetonate), Ta(N(CH₃)₂)₅[penta-methyl-amino-tantalum], Ta(DMP)₄C1 [tantalum chlro-tetradipivaloymethane], Ta(OCH₃)₅[tantalum pentamethoxide], or the like have been used as a precursor.

During the deposition process, these precursors react with O₂ to generate TaO₅ easily. However, a byproduct of carbon hydrogen compounds like carbon (C) exist within the thin TaO₅ film. These byproducts are important factors to cause the leakage current of the thin inter-poly dielectric film. Furthermore, these weaken the dielectric strength significantly.

### SUMMARY OF THE INVENTION

The present invention is contrived to solve the above problems and an object of the present invention is to improve the lifetime of a thin film and improve the reliability by lowering the leakage current and increasing the insulating breakdown voltage since carbon components remain within a thin dielectric film.

Another object of the present invention is to provide a dielectric film that can be implemented with a simple number of unit process and be formed at a low process temperature.

In order to accomplish the above object, a method of manufacturing a semiconductor device according to the present invention, is characterized in that it comprises the steps of forming a first doped polysilicon layer being a lower electrode on a semiconductor substrate, forming a Ta₂O₅ dielectric film using a carbon-free precursor and a reaction gas, and forming an upper electrode on the dielectric film.

Preferably, the carbon-free precursor is TaF₅ or TaCl₅.

Further, the method may include the step of nitrifying the surface of silicon, after the step of forming the first doped polysilicon layer. After the step of forming the dielectric film, the amorphous Ta₂O₅ surface may be nitrified by an annealing process under of NH₃ or N₂/H₂ ambient at a temperature of 300 through 600° C. using plasma or RTP.

### BRIEF DESCRIPTION OF THE DRAWINGS

The aforementioned aspects and other features of the present invention will be explained in the following description, taken in conjunction with the accompanying drawings, wherein:

FIG. 1A through FIG. 1E are cross sectional views of semiconductor devices for explaining a method of manufacturing a dielectric film according to a preferred embodiment of the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

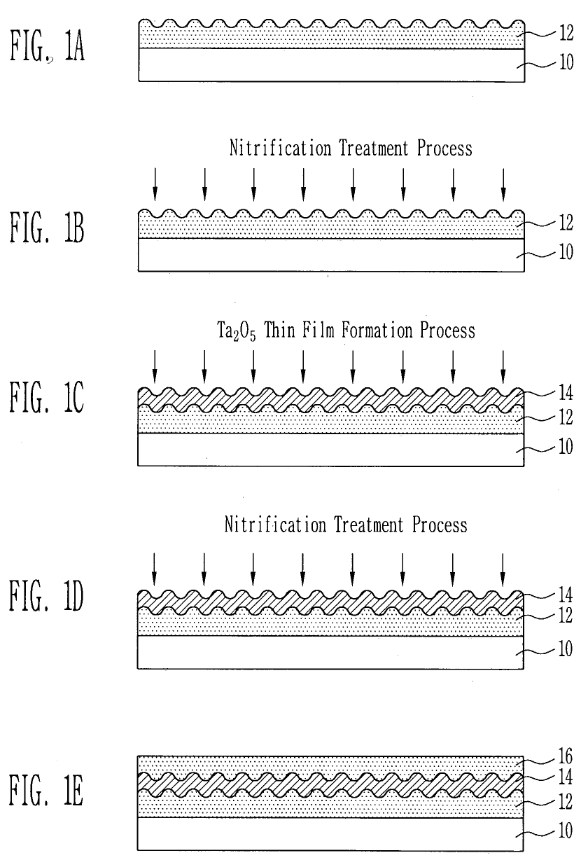

A method of manufacturing a semiconductor device according to one embodiment of the present invention will be below described by reference to FIG. 1A through FIG. 1E.

For convenience of explanation, an embodiment wherein the present invention is applied to a thin inter-poly dielectric film used for a cell transistor in the flash memory device will be described.

Referring now to FIG. 1A, a poly-silicon layer 12 being a storage node is formed on a semiconductor substrate 10. The doped polysilicon layer 12 is used as a floating gate of the flash memory. For example, the doped polysilicon layer 12 may be deposited using a low-pressure chemical vapor deposition (LPCVD) technology. An electrode module of a Ta₂O₅ inter-poly dielectric thin film of the cell transistor in the flash memory is formed. Preferably, in order to increase the charge capacitance value of the Ta₂O₅ cell transistor, the polysilicon layer of a HSG (hemi spherical grain) shape may be formed on a lower electrode of the floating gate, which may be used as the storage node. In the HSG process, after an amorphous silicon film is deposited, Si₂H₆ or SiH₄ gas is dissolved within a vacuum anneal chamber at a temperature of 500 through 600° C. and pressure of 10⁻¹⁰ through 10⁻⁸ Torr so that Si₂H₆ or SiH₄ gas serves as a nucleus generating site. Next, as silicon (Si) particles move toward the nucleus generating site through the annealing process, irregular curved surfaces are formed on the surface of the amorphous silicon film. Thereby, an effective surface area significantly larger than the flat surface can be obtained.

After the doped polysilicon layer is formed, a process of removing a native oxide film through surface treatment using HF gas or HF solution may be additionally added. Also, in the surface-treatment step, the interface may be treated using compounds including NH₄OH solution or H₂SO₄ before and/or after HF surface treatment.

Referring to FIG. 1B, in order to prevent formation of a low-dielectric oxide film (SiO₂), the surface may be nitrified in a chemical vapor deposition (CVD) chamber by means of an in-situ process under NH₃ or N₂/H₂ gas ambient at a temperature of 300 through 600° C. for 30 seconds through 5 minutes right before Ta₂O₅ is deposited by discharging plasma. Another nitrification treatment process includes a RTN (rapid thermal nitrification) process at a temperature of 750 through 900° C. for 1 through 30 minutes, etc. The thickness of the nitride film by the nitrification process is, for example, 5 through 30 Å. Also, a process of annealing the low-dielectric oxide film (SiO₂) under NO₂ or O₂ atmosphere may be added in order to remove the dangling bonds.

Meanwhile, the nitrification process can be applied to the interface of the thin Ta₂O₅ film and the doped polysilicon layer after the thin Ta₂O₅ film is deposited, which will be later described.

By reference to FIG. 1C, an amorphous Ta₂O₅ thin film 14 is deposited on the polysilicon layer 12 by means of the CVD process, using a solid source such as TaF₅[tantalum pentafluoride, evaporized at a temperature of over 95° C.] or TaCl₅[tantalum pentachloride, evaporized at a temperature of over 144° C.], which are carbon-free TaF₅ precursors.

The TaF₅(tantalum pentafluoride) precursor of the solid source is evaporized within a bubbler where a temperature of 65 through 95° C. remains constantly to produce chemical vapor of Ta component. TaF₅ vapor thus obtained is applied to the CVD chamber via the supply tube wherein a temperature of 100 through 150° C. remains in order to prevent condensation.

Another method of obtaining chemical vapor of Ta components includes evaporizing the TaCl₅ precursor at a constant temperature of 95 through 150° C. to produce Ta vapor. Ta vapor is applied to the CVD chamber via the supply tube wherein a temperature of 50 through 190° C. is kept.

Meanwhile, active hydrogen and active oxygen of a reaction gas may be obtained using a remote plasma method in which active hydrogen and active oxygen are ionized by a glow discharge of plasma in a plasma generator which is disposed in external to the CVD chamber and are again injected into the CVD chamber. In a state where oxygen and hydrogen are supplied to the CVD chamber, ionized hydrogen and oxygen may be obtained by in-situ discharging plasma. The reactivity can be improved if oxygen and hydrogen necessary in the reaction are used with the ionized oxygen and hydrogen using the glow discharge. Thus, as the deposition speed of the thin Ta₂O₅ film is made faster, the thin Ta₂O₅ film of a good quality is obtainable.

Next, a surface chemical reaction of Ta chemical vapor, active hydrogen and active oxygen are induced on the wafer of below 200° C. through flow control within the LPCVD chamber, thereby forming the thin Ta₂O₅ film. Another method includes supplying O₂ vapor of below 300 sccm and TaF₅ vapor of below 100 sccm to the CVD chamber and then reacting them with the active hydrogen. At this time, the temperature of the wafer remains below 200° C.

The above principle of forming the dielectric film can be represented as the following equations.

5H₂+2TaF₅->10HF+2Ta [Equation 1]

4Ta+5O₂->2Ta₂O₅ [Equation 2]

As can be seen from the reaction equations, ionized active hydrogen combines with F of TaF to produce HF gas (Equation 1). Also, active oxygen combines with the substitution type Ta atom to produce Ta₂O₅ (Equation 2). As HF gas generated in this process is a volatile gas, it is completely removed during the reaction. Thus, as byproduct such as carbon component as well as fluoride-series compounds can not remain within the deposited amorphous Ta₂O₅ inter-poly dielectric thin film, the dielectric film of a good quality can be obtained.

In the mentioned method of manufacturing the dielectric film, the temperature of the wafer is low, for example 200° C., a peroxide reaction does hardly occur during the deposition process. The low dielectric oxide film is thus formed in thickness of no more than 10 Å at the storage node and the interface. Therefore, considering that the oxide film at the interface is formed in thickness of 30 Å when the conventional thin Ta₂O₅ dielectric film is manufactured, the equivalent thickness (Tox) of the oxide film could be lowered more, which has an advantage that a sufficient high capacitance can be obtained.

In other words, the Ta₂O₅ film of an amorphous state has a dielectric constant of about 25. This value is higher than the dielectric constant (ε<15) of the amorphous Ta₂O₅ thin film and the dielectric constant (ε=17 through 20) of the amorphous crystallized Ta₂O₅ film, which are obtained using the organic metal compounds as a precursor. Thus, the annealing process for increasing the dielectric constant through high-temperature annealing is not necessarily required. Further, even though the low-temperature and high-temperature annealing process for removing carbon component remaining within the thin Ta₂O₅ film are not performed, a stable electrical characteristic could be obtained.

Meanwhile, in order to introduce crystallization of the amorphous Ta₂O₅ thin film, a subsequent high-temperature annealing process may be performed using RTP or an electric furnace at a temperature of 600° C. through 950° C. Also, in order to improve structural defects or structural irregularity including cracks or pin holes occurring in the process of forming the thin Ta₂O₅ film or structural defects or structural irregularity including cracks or pin holes occurring in the process of crystallizing the thin Ta₂O₅ film, a surface oxidization process may be performed using plasma under N₂O or O₂ atmosphere at a temperature of 300 through 600° C.

Next, in order to prevent formation of an interfacial oxide film that may be formed on the interface with the upper electrode by a subsequent annealing process after the thin Ta₂O₅ film of an amorphous state is deposited, a surface nitrification process under NH₃ or N₂/H₂ atmosphere using plasma at a temperature of 300 through 600° C. for 1 through 10 minutes or a RTN (rapid thermal nitrification) process at a temperature of 750 through 900° C. for 1 through 30 minutes may be performed.

Thereafter, a second polysilicon layer 16 is deposited to form a control gate being an upper electrode (or plate electrode). At this time, the control gate may be used instead of the polysilicon layer 16. The control gate may be formed using TiN, TaN, W, WN, WSi, Ru, RuO₂, Ir, IrO₂ or Pt metal. The step of forming the upper electrode includes performing depositing TiN, TaN, WN or Wsi as a conduction barrier in thickness of about 50 through 600 Å and stacking the polysilicon layer.

Then, a photolithography and an etch process are performed. Thereby, the process of forming the cell transistor in the flash memory device being a nonvolatile memory device is finished.

As mentioned above, according to the present invention, as a Ta₂O₅ dielectric thin film is formed using a carbon-free precursor, the level of the leakage current is lowered more than twice and the insulating breakdown voltage is increased. Therefore, the present invention has advantageous effects that it can extend the lifetime of the thin film and thus improve reliability of the device, particularly if the Ta₂O₅ dielectric thin film is used as an inter-poly dielectric material.

Furthermore, the present invention has advantageous effects that it can reduce the number of the unit process and can reduce the process temperature itself, compared to the prior art wherein organic compounds are used as a precursor.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A method of manufacturing a semiconductor device, comprising the steps of:
forming a first doped polysilicon layer being a lower electrode on a semiconductor substrate;
forming a Ta₂O₅ dielectric film using a carbon-free precursor and reaction gases; and
forming an upper electrode on the dielectric film.

2. The method as claimed in claim 1, wherein the carbon-free precursor is TaF₅ or TaCl₅.

3. The method as claimed in claim 1, further comprising the step of making the first doped poly-silicon layer have a HSG (hemi-spherical-grain) structure.

4. The method as claimed in claim 1, wherein the upper electrode is a second doped polysilicon layer.

5. The method as claimed in claim 1, wherein the reaction gases includes active hydrogen and active oxygen.

6. The method as claimed in claim 5, wherein the control gate is formed using one of TiN, TaN, W, WN, WSi, Ru, RuO₂, Ir, IrO₂ or Pt metal.

7. The method as claimed in claim 1, wherein the step of forming the upper electrode includes depositing TiN, TaN, WN or Wsi with a thickness of 50 through 600 Å as a conduction barrier and staking a polysilicon layer.

8. The method as claimed in claim 1, further comprising the step of nitrifying the surface of silicon, after the step of forming the first doped polysilicon layer.

9. The method as claimed in claim 8, wherein the nitrification step is performed in-situ under NH₃ or N₂/H₂ atmosphere using plasma at a temperature of 300 through 600° C. for 30 seconds through 5 minutes, and wherein the thickness of the nitrified film is 5 through 30 Å.

10. The method as claimed in claim 8, wherein the nitrification step includes annealing the surface of silicon under NH₃ atmosphere at a temperature of 650 through 950° C. using RTP (rapid thermal process) and wherein the thickness of the nitrified film is 5 through 30 Å.

11. The method as claimed in claim 8, wherein the step of forming the first doped polysilicon layer and the step of nitrifying the surface of polysilicon are consecutively performed.

12. The method as claimed in claim 1, further comprising the steps of removing a native oxide film through surface treatment using HF vapor or HF solution, after the first doped polysilicon layer is formed.

13. The method as claimed in claim 12, wherein in the surface treatment step, the interface is treated using compounds including NH₄OH solution or H₂SO₄ before and/or after HF surface treatment.

14. The method as claimed in claim 1, wherein before the step of forming the dielectric film, an annealing process is performed in order to remove dangling bonds under NO₂ or O₂ atmosphere.

15. The method as claimed in claim 1, wherein in the step of forming the dielectric film, a TaF₅ precursor is evaporized at a temperature of 65 through 95° C. to generate Ta vapor and is then injected into a CVD chamber via a supply tube with a temperature of 100 through 150° C., and wherein the Ta components form Ta₂O₅ using active hydrogen and active oxygen under a pressure of below 10 mTorr.

16. The method as claimed in claim 1, wherein in the step of forming the dielectric film, TaCl₅ precursor is evaporized at a temperature of 95 through 150° C. to generate Ta vapor and is then injected into a CVD chamber via a supply tube with a temperature of 150 through 190° C., and wherein the Ta components form Ta₂O₅ using active hydrogen and active oxygen under a pressure of below 10 mTorr.

17. The method as claimed in claim 1, wherein the step of forming the dielectric film includes introducing a surface chemical reaction of Ta chemical vapor, active hydrogen and active oxygen on a wafer having a temperature of below 200° C. through controlled flow within a LPCVD chamber, and wherein the thickness of the nitrified film is 5 through 20 Å.

18. The method as claimed in claim 1, wherein after the step of forming the dielectric film, the amorphous Ta₂O₅ surface is nitrified by an annealing process under of NH₃ or N₂/H₂ ambient at a temperature of 300 through 600° C. using plasma or RTP, and wherein the thickness of the nitrified film is 5 through 20 Å.

19. The method as claimed in claim 18, wherein in order to introduce crystallization of-the amorphous Ta₂O₅ thin film, the amorphous Ta₂O₅ thin film is experienced by a subsequent high-temperature annealing process using RTP or an electric furnace at a temperature of 600 through 950° C.

20. The method as claimed in claim 1, wherein after the thin Ta₂O₅ film is formed, the surface of the thin Ta₂O₅ film is oxidized under N₂O or O₂ ambient using plasma at a temperature of 300 through 600° C.
